(19) United States
(12) Patent Application Publication
(10) Pub. No.: US 2012/0235825 A1
(43) Pub. Date: Sep. 20, 2012

(54) METHOD AND APPARATUS FOR DETECTING A FAULT IN AN ACTIVE LINE, NEUTRAL RETURN LINE OR EARTH RETURN PATH OF AN ELECTRICAL NETWORK

(75) Inventors: ERICKSON BRUCE MYERS, Claremont (AU); Bryan Douglas Holter, Taroona (AU); William John Godwin, North Hobart (AU); Stanley Edward Thomas Hutchinson, Claremont (AU)

(73) Assignee: AURORA ENERGY PTY LTD, Hobart (AU)

(21) Appl. No.: 13/275,150

(22) Filed: Oct. 17, 2011

Related U.S. Application Data
(63) Continuation of application No. PCT/AU2009/001657, filed on Dec. 18, 2009.

(30) Foreign Application Priority Data
Apr. 17, 2009 (AU) 2009901651

(51) Int. Cl. G01R 31/02; G08B 21/00; G06F 19/00

(52) U.S. Cl. 340/652; 702/58

(57) ABSTRACT

Detecting a discontinuity or impedance irregularity in an active line, a neutral return line and/or an earth return path of a power distribution network is disclosed. In one aspect, the apparatus is configured to measure a change in voltage and/or current associated with a deliberate switching of a known impedance and/or a naturally occurring random switching of an impedance in the electrical network wherein the change in voltage and/or current flow results from a discontinuity or impedance irregularity in the active line, neutral line and/or earth return path. The apparatus includes an algorithm for identifying discontinuity or impedance irregularity in the presence of allowable variation in voltage and/or current that may mimic or hide a discontinuity or impedance irregularity in the active line, neutral return line and/or earth return path including a reverse current flow through the earth return path.

### CROSS-REFERENCE TO RELATED APPLICATIONS

This application is a continuation application, and claims the benefit under 35 U.S.C. §§120 and 365 of PCT Application No. PCT/AU2009/001657, filed on Dec. 18, 2009, which is hereby incorporated by reference. PCT/AU2009/001657 also claimed priority from Australian Patent Application No. 2009901651, filed on Apr. 17, 2009, which is hereby incorporated by reference.

### BACKGROUND

1. Field

The described technology generally relates to monitoring and/or detecting faults in a supply line of an electrical power distribution network.

2. Description of the Related Technology

The electricity power supply industry generally has an earthed return system to provide a protected electrical return path in the case of faults. Flow of current in the system is mostly between the active and neutral return lines. The system allows for current to flow between the active line and the earth return path when a fault occurs in equipment connected to the system.

Because current can flow in one or two circuits (neutral and earth), a discontinuity or impedance irregularity in one circuit (neutral or earth) can go undetected for a period of time without any indication of danger until the second circuit (neutral and earth) also becomes defective.

For example, a high impedance or discontinuity in a neutral line or wire may allow current to flow between active and earth. However, the earth return path may become ineffective or defective over time due to a number of factors including drying out of the soil, a faulty connection or cable damage following work carried out on plumbing or the like. When a sound earth return path is not in place current may flow to earth through other paths such as water pipes and storm drains or it may not flow at all. The latter may cause a rise in voltage potential above earth and create a danger of electric shock to persons with a potential for injury or death.

In addition, a high impedance in an active line or path can result in electrically induced heating and/or electrical arcing that may result in a potential for fire, property damage, injury and/or death.

### SUMMARY

One inventive aspect is a method of detecting a fault such as a discontinuity or impedance irregularity in a supply line including an active line, a neutral return line, or an earth return path of an electrical network, wherein presence of a voltage potential may result in a danger or risk of electric shock to persons with a possibility of injury or death or wherein presence of electrically induced heating and/or electrical arcing may result in a danger or risk of fire.

One embodiment may detect a discontinuity or impedance irregularity in an active line (or lines), a neutral return line (or lines) and/or an earth return path (or lines) of an electrical power distribution network. One embodiment may detect the discontinuity or impedance irregularity at a consumer site. One embodiment may detect the discontinuity or impedance irregularity by monitoring and/or measuring a property or properties associated with the supply lines. The property or properties may include a change in loop impedance, current flow in the active and neutral supply lines and the earth return path and/or a voltage change in an electrical circuit associated with the network. Changes in current flow in the active and neutral lines and the earth return path as well as in voltage may be caused by naturally occurring random and/or deliberate changes in impedance of the network including the active line, neutral return line and earth return path. One embodiment may include one or more algorithms which may distinguish allowable variations in current flow as well as variations resulting from changes in “nominal supply voltage” and other voltage changes including steps, sags, spikes, etc. attributable to normal network operations that may either mimic or hide a discontinuity or impedance irregularity in an active line, neutral return line and or earth return path. The algorithm(s) may also distinguish current flow in the earth return path at a consumer site resulting from discontinuities or impedance irregularities in an active line, neutral return line or earth return path occurring at other installations that may mimic or hide a discontinuity or impedance irregularity in an active line, neutral return line and/or earth return path at the consumer site.

The electrical properties as well as physical dimensions and characteristics of electrical circuits that develop a discontinuity or impedance irregularity in an active line, neutral line or earth return path may differ from those present in electrical circuits that retain an intact active line, neutral line or earth return path.

Given that the sum of the magnitude and direction of current flow in the active and neutral lines and the earth return path of an electrical network under normal circumstances should equal zero, and given also that the current flow is dependant upon serial and parallel impedances of the active and neutral lines and the earth return path as well as supply voltage magnitude and phase, a measurement and comparison of changes in the current flow and supply voltage, may reflect changes in impedances of the active and neutral lines and the earth return path of an electrical network. Under a condition of a discontinuity or impedance irregularity in the neutral line, loop impedance of the active neutral/earth return path will increase as will the current flow in the earth-return path. Under a condition of a discontinuity or impedance irregularity in the active line, loop impedance of the active neutral/earth return path will increase while the currents in the neutral and active lines will remain substantially unchanged under similar load conditions. Under a condition of a discontinuity or impedance irregularity in the earth return path, loop impedance of the active neutral/earth return path will increase while the current in the neutral line will also increase.

However, current flow in both the earth return path as well as the neutral line can result from discontinuities or impedance irregularities in a neutral return line or earth return path occurring at other installations. A phase dependant current flow originating at other installations may mimic or hide a discontinuity or impedance irregularity in the neutral return line or earth return path at the consumer site where the current is being measured.

Given a stable supply voltage, an expected voltage drop in a circuit may depend upon series and parallel impedances in the circuit, impedance of the active line, neutral line return, and impedance of the earth return path. Under a condition of a discontinuity or impedance irregularity in the neutral line the expected voltage drop may depend primarily on the value of the earth return path impedance, which will generally be measurably greater than in the case of an intact neutral.

Measurement of a change in current flow and a drop in line voltage resulting from a change in impedance in a network may be used to indicate a discontinuity or impedance irregularity in a supply line of an electrical power distribution network. A measurable change in current flow and voltage drop may result from naturally occurring random switching of impedances within an electrical network, or may result from deliberate or planned switching of impedance in the electrical network.

Measurement of a change in current flow and voltage drop resulting from naturally occurring random switching of impedances within an electrical network, or from deliberate or planned switching of impedance in the electrical network can be used to estimate magnitude and condition of serial and parallel impedances of the active and neutral lines and the earth return path.

As the impedance of a neutral return line is generally less than that of an earth return path, the presence of a voltage potential under conditions of high neutral return impedance may result in a danger of electric shock to persons with a possibility of injury or death.

Another aspect is an apparatus for detecting a discontinuity or impedance irregularity in a supply line and or earth return path of an electrical power distribution network. The discontinuity or impedance irregularity may be present anywhere between a supply transformer and a point of connection of the apparatus to the power distribution network. The apparatus may be installed in a customer's premises at a convenient location such as a switchboard or it may be associated with metering equipment.

The apparatus may be adapted to differentiate between a circuit having an intact neutral return line and or earth return path, and a circuit having a discontinuity or impedance irregularity in an active line, a neutral return line and or earth return path. The apparatus may measure a change in current flow and line voltage resulting from a change in impedance in a network that may be used to indicate a discontinuity or impedance irregularity in a supply line of an electrical power distribution network. A measurable change in current flow and voltage drop may result from naturally occurring random switching of impedances within an electrical network, or may result from deliberate or planned switching of impedance in an electrical network. The apparatus may measure a change in current flow and voltage resulting from naturally occurring random switching of impedances within an electrical network, or from deliberate or planned switching of impedance in an electrical network, in order to estimate magnitude and condition of serial and parallel impedances of the active and neutral lines and the earth return path.

Electricity distribution supply networks generally provide electricity at a defined “nominal supply voltage” that may vary between allowable high and low bounds. In addition to these allowable variations in “nominal supply voltage” are voltage changes, (steps, sags, spikes, etc.) resulting from normal network operations. These may include voltage rises or drops due to various factors including loads imposed on the local or distribution network, overloading of transformers, switching, lightning strikes, re-closer operation, etc.

As naturally occurring voltage sags and spikes in a supply voltage may result in voltage drops or rises that may mimic or hide a discontinuity or impedance irregularity in an active line, a neutral supply line and/or earth return path, and naturally occurring changes in local and distribution network impedances may result in a change to current flow that may mimic or hide a discontinuity or impedance irregularity in an active line, a neutral supply line and or earth return path, the apparatus may include an algorithm that may minimise impact of such anomalous events on reliable detection of the discontinuity or impedance irregularity in an active line, a neutral supply line and or an earth return path. Thus the algorithm may facilitate identification of a discontinuity or impedance irregularity in an active line, a neutral supply line and/or an earth return path under anomalous voltage or current flow conditions.

A reverse current flow through the earth return path from other installations may also alter current flow between the active and neutral lines and the earth return path. Thus the algorithm may allow for estimation of the magnitude and condition of serial and parallel impedances of the active and neutral lines and the earth return path under conditions of reverse current flow in the earth return path and may identify potential discontinuities or impedance irregularities at other customer sites.

The apparatus may include means such as an audible or visual signal or an alarm or an electronic signal to communicate to the consumer and/or a third party that an active line, a neutral return line or earth return path may contain a discontinuity or impedance irregularity.

The apparatus may include means to interrupt current flow in the active line suppling a consumer site in the event that an active line, a neutral return line or earth return path may contain a discontinuity or impedance irregularity.

Another aspect is an apparatus for detecting a discontinuity or impedance irregularity in an active line, a neutral return line and/or an earth return path of an electrical power distribution network including the active line, neutral return line and earth return path, the apparatus including: means for measuring a change in voltage and/or current flow associated with a deliberate switching of a known impedance and/or a naturally occurring random switching of an impedance in the electrical network wherein the change in voltage and/or current flow is due to a discontinuity or impedance irregularity in the active line, neutral line and/or earth return path; means for implementing a first algorithm for identifying the discontinuity or impedance irregularity in presence of allowable variation in voltage and/or current flow that may mimic or hide a discontinuity or impedance irregularity in the active line, neutral return line and/or earth return path including a reverse current flow through the earth return path; and means for comparing a result of the measuring with a reference to provide an indication of the discontinuity or impedance irregularity.

The apparatus may include means for measuring a voltage change in the electrical network associated with the deliberate switching, wherein the voltage change is due to the discontinuity or impedance irregularity in the neutral return line and/or earth return path.

The first algorithm may be adapted for identifying the discontinuity or impedance irregularity in presence of allowable variation in nominal supply voltage to the electrical network including a voltage change resulting from network operations that mimic or hide a discontinuity or impedance irregularity in the active line, neutral return line and or earth return path.

The apparatus may include means for implementing a second algorithm that includes an estimation of magnitude and condition of serial and parallel impedances of the active and neutral lines and the earth return path in presence of allowable variation in nominal supply voltage to the electrical network including a voltage change resulting from network operations that mimic or hide a discontinuity or impedance irregularity in the active line, neutral return line and/or earth return path.

The second algorithm may include an estimation of variation in current flow that may mimic or hide a discontinuity or impedance irregularity in the active line, a neutral supply line and/or earth return path including a reverse current flow through the earth return path that may alter current flow between the active and neutral lines and the earth return path.

Another aspect is a method for detecting a discontinuity or impedance irregularity in an active line, a neutral return line and/or an earth return path of an electrical power distribution network including the active line, neutral return line and earth return path, the method including: measuring a change in voltage and/or current flow associated with a deliberate switching of a known impedance and/or a naturally occurring random switching of an impedance in the electrical network wherein the change in voltage and/or current flow is due to a discontinuity or impedance irregularity in the active line, neutral line and/or earth return path; implementing a first algorithm for identifying the discontinuity or impedance irregularity in presence of allowable variation in voltage and/or current flow that may mimic or hide a discontinuity or impedance irregularity in the active line, neutral return line and/or earth return path including a reverse current flow through the earth return path; and comparing a result of the measuring with a reference to provide an indication of the discontinuity or impedance irregularity.

The method may include measuring a voltage change in the electrical network associated with the deliberate switching, wherein the voltage change is due to the discontinuity or impedance irregularity in the neutral return line and/or earth return path.

The method may include the step of implementing a second algorithm that includes an estimation of magnitude and condition of serial and parallel impedances of the active and neutral lines and the earth return path in presence of allowable variations in nominal supply voltage to the electrical network including a voltage change resulting from network operations that mimic or hide a discontinuity or impedance irregularity in the active line, neutral return line and/or earth return path.

### BRIEF DESCRIPTION OF THE DRAWINGS

FIG. 1 shows a simplified diagram of a typical installation.

FIG. 2 shows a simplified diagram of a faulty installation.

FIG. 3 shows a representation of a local network including an intact neutral return line.

FIG. 4 shows a representation of a local network including a discontinuous neutral return line.

FIG. 5 shows a representation of normal variations in “nominal voltage” including randomly occurring voltage sags and spikes.

FIG. 6 shows a block diagram of an apparatus for detecting a discontinuity in an electrical power distribution system.

FIG. 7 shows a diagram of one form of apparatus according to one embodiment.

5

FIG. 8 shows a flow diagram of one form of algorithm.

### DETAILED DESCRIPTION

Embodiments will be described with reference to the accompanying drawings. Reference herein to a supply line including an active line, a neutral return line and/or an earth return path of an electrical power distribution network includes a reference to a plurality of supply lines including a plurality of active lines, neutral return lines and/or earth return lines of the electrical power distribution network as the case may be.

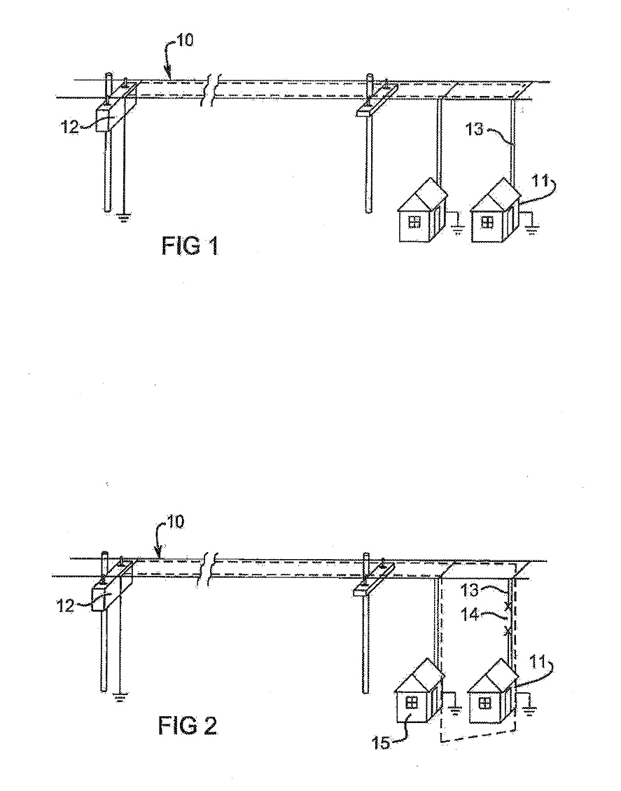

FIG. 1 shows a simplified example of a domestic electrical power supply installation including overhead transmission line 10 between house 11 and distribution transformer 12. The installation has an intact neutral return line 13 between house 11 and distribution transformer 12.

FIG. 2 shows the same domestic power supply installation including a break 14 in the neutral return line 13 to house 11. In this case the earth and the water-pipe bond form a secondary connection with the neutral connection of house 15 next door and/or with an earth return connection of distribution transformer 12.

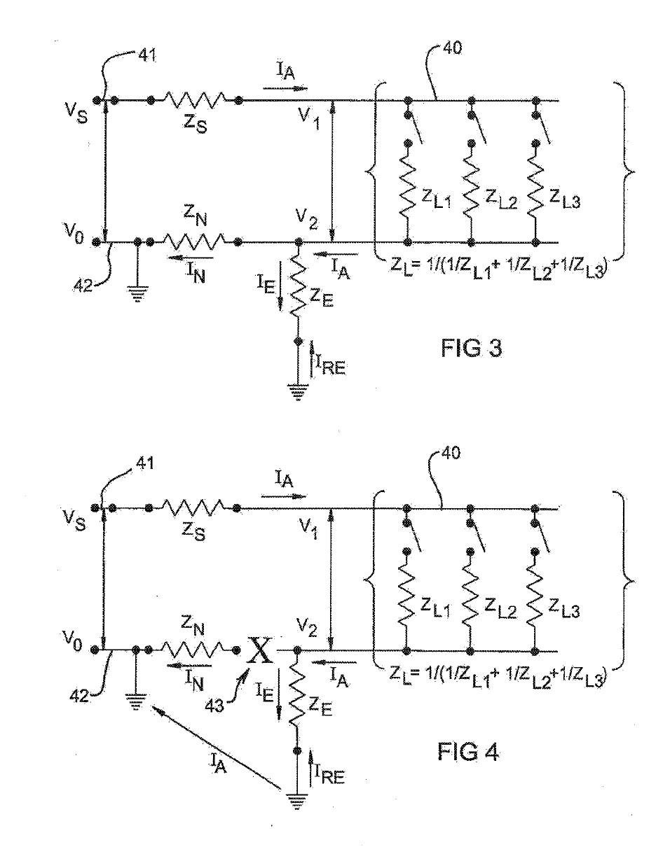

FIG. 3 shows a representation of a local network 40 including a plurality of naturally switched loads Z_{L} made up of Z_{L1}, Z_{L2}, Z_{L3} connected between active line 41 and neutral line 42. A local current I_{A} flows between the active line and the neutral line/earth return path determined by voltage V₁ across the local network and the total local network impedance Z_{L}. The impedance Z_{N} represents the neutral impedance associated with neutral line 42 while local earth impedance is represented by Z_{E}. The equivalent impedance Z_{NE} of parallel impedances Z_{N} and Z_{E} may be represented by

Z_{NE}=1(1/Z_{N}+1/Z_{E})

The voltage V₂ at a common connection point of the neutral line and the earth return path is dependant upon the voltage across the local network, V₁ the total network impedance Z_{L} and the equivalent parallel impedance Z_{NE}.

V₂=V₁*Z_{NE}(Z_{NE}+Z_{L})

Local current I_{A} flows through parallel impedances Z_{N} and Z_{E} as currents I_{N} and I_{E} respectively based upon their relative impedances such that

I_{N}*Z_{N}=*Z_{E} or I_{N}=I_{E}*Z_{E}/Z_{N}

Since the sum of magnitude and direction of current flows in the active and neutral lines and the earth return path of an electrical network under normal circumstances should equal zero this implies that

I_{A}=I_{N}+I_{E} or I_{E}=I_{A}−I_{N}

It follows that I_{N}=I_{A}*Z_{E}/(Z_{N}+Z_{E})

Under normal circumstances when both the neutral line and earth return path are continuous and regular, the magnitude of and relative difference between impedances Z_{N} and Z_{E} is generally such that when
Z_{NE}→0 hence Z_{NE}/(Z_{NE}+Z_{L})→0 and V₂→0
Z_{E}>>Z_{N} hence I_{N}>>I_{E} and I_{N}→I_{A}

Under various conditions, a reverse earth return current I_{RE} may be present in the network originating from other networks. This current may distort measured values of I_{N} and I_{E}, and may be in-phase with networks active current or may be out of phase with the active current.

FIG. 4 shows local network 40 of FIG. 3 including a discontinuity 43 in neutral return line 42. Discontinuity 43 or an impedance irregularity may give rise to a change in neutral impedance Z_{N}.

Under these circumstances the magnitude and relative difference between impedances Z_{N} and Z_{E} is generally such that when
Z_{N}→∞ hence Z_{NE}=1/(1/Z_{N}+1/Z_{E})→Z_{E}
Z_{N}<<∞ hence V₂→0
Z_{N}→ hence Z_{NE} increases and V₂ increases
Z_{E}<<Z_{N} hence I_{N}<<I_{E} and I_{N}→0

In FIG. 4 the local current I_{A} flows exclusively or primarily via earth impedance Z_{E} resulting in a change in relative magnitude of current flows I_{N} and I_{E} which can be compared to a reference or standard relative magnitude to provide an indication of the discontinuity 43 or an impedance irregularity in neutral line 42.

Under a condition of discontinuity 43 or an impedance irregularity in a neutral line voltage V₂ is greater than it would be under a condition of a continuous or regular neutral line. The increase in voltage V₂ may be detected by comparing V₂ to a reference or standard voltage to provide an indication of the discontinuity 43 or impedance irregularity in neutral return line 42.

Under these circumstances, an increased earth return current I_{E} may appear on one or more other networks as a reverse earth return current I_{RE}. This current may distort measured values of I_{N} and I_{E}, the ratio of I_{N}/I_{A}, on these other networks, and may be in-phase with other networks active current, or may be out of phase with other networks active current.

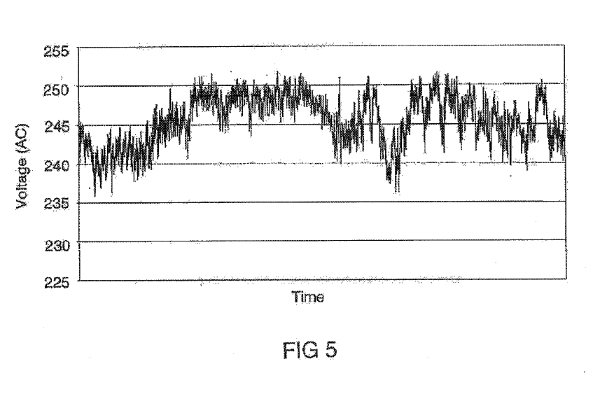

FIG. 5 provides an example of line voltage variations that may be present in a typical electrical distribution network. The variations include variations in “nominal supply voltage” and voltage changes such as steps, sags, spikes, etc. due to normal network operations, including voltage changes or drops due to loads imposed on a local or distribution network, overloading of transformers, switching, lightning strikes, re-closer operations, etc.

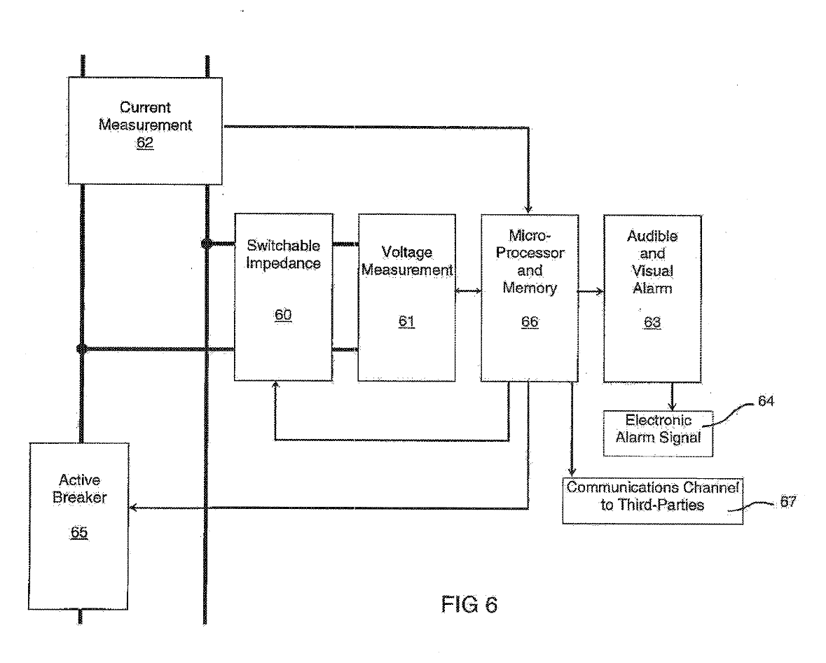

FIG. 6 shows a conceptual diagram of one form of apparatus for detecting a discontinuity or impedance irregularity in an electrical power distribution system. The apparatus includes switchable impedance block 60 for applying an impedance to a line voltage supply. Impedance block 60 includes means for controlled switching of impedance to a circuit associated with the line voltage supply.

The apparatus includes voltage measurement block 61 including a means for converting the voltage input from an analog into a digital representation by using an analog to digital converter.

The apparatus includes current measurement block 62 including current sensing means such as transformers or shunts in series with the active and neutral supply lines for measuring current flow and a means for converting the voltage input from the current sensing transformers or shunts from an analog into a digital representation by using an analog to digital converter. The current measurement block 62 may include means to measure current flow in a single or multiple active phase lines either individually or as a single current flow.

The apparatus includes an audible and/or visual signal or alarm 63 and/or an electronic alarm signal block 64 to communicate to a consumer and/or a third party that an active line, a neutral return line and or earth return path may contain a discontinuity or impedance irregularity.

The apparatus may include an active current flow breaker block 65 that may be used to interrupt active current flow in the event of a discontinuity or impedance irregularity in an active line, a neutral return line and or earth return path. Active breaker block 65 may be controlled by a microprocessor and memory block 66.

Microprocessor and memory block 66 may be adapted for controlling impedance block 60, voltage measurement block 61, current measurement block 62, alarm signal block 63, and active current flow breaker block 65 as well as for determining and/or confirming whether the supply line has a discontinuity or impedance irregularity in an active line, a neutral return line and/or earth return path. The apparatus may include a communications channel block 67 to allow the apparatus to communicate with an external third party and may provide to the third party information on a discontinuity or impedance irregularity in an active line, a neutral return line and/or earth return path.

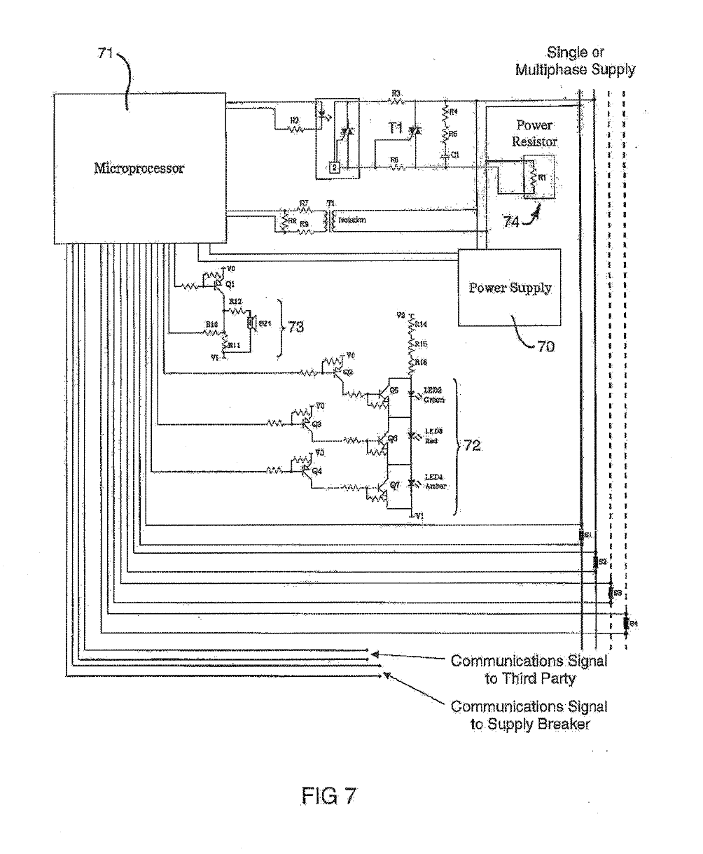

FIG. 7 shows a schematic diagram of one form of apparatus for detecting a fault in an active line, neutral line or earth return path. The apparatus includes a power supply 70 which provides power for operation of microprocessor 71, alarm lights 72, and audible alarm 73. The apparatus includes switchable impedance 74 consisting of power resistor R1 switched by means of triac T1 under control of microprocessor 71. Microprocessor 71 includes a software implementation of an algorithm as described below. Microprocessor 71 measures line voltage and current by means of an inbuilt analog to digital converter, controls operation of switchable impedance 74 via triac T1 and controls operation of alarm lights 72, audible alarm 73 and communications to external devices and third parties.

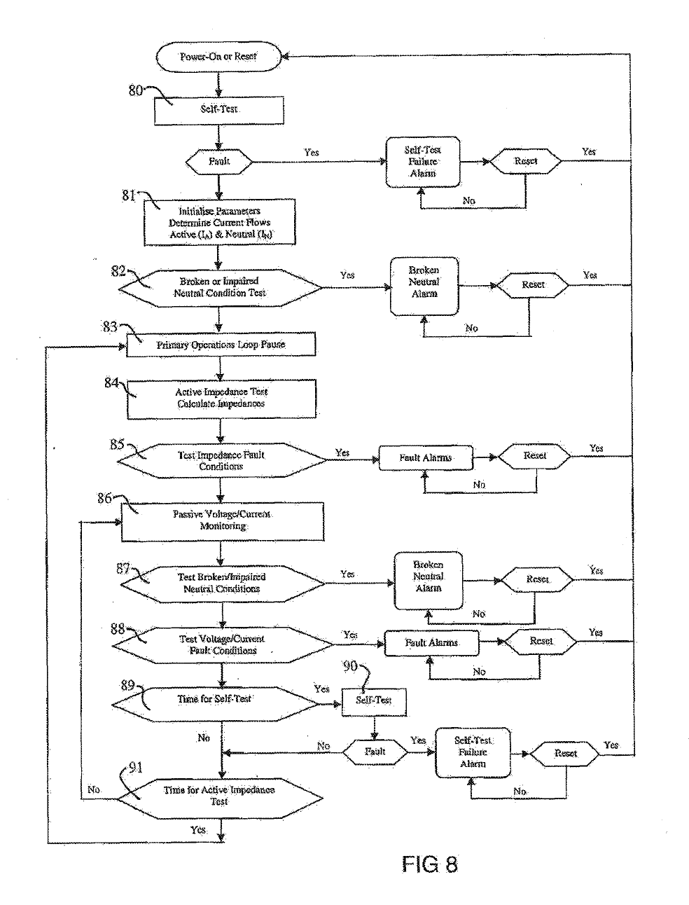

FIG. 8 shows a flow diagram for an example algorithm that may allow for identification of a discontinuity or impedance irregularity in an active line, neutral supply line and or earth return path in a network or associated networks:
Under anomalous voltage conditions such as allowable variations in “nominal supply voltage” and voltage changes, (steps, sags, spikes, etc.) resulting from normal network operations.
Under anomalous changes in local and distribution network impedances that may result in changes to current flows resulting from normal network operations.
Under reverse current flow through the earth return path from other installations that may alter the current flow between the active and neutral lines and the earth return path.

The algorithm includes a start-up and self-test routine 80 that checks whether the user interface and apparatus hardware is operating within defined parameters, and is enabled upon apparatus power-up or restart and/or on a timed basis during operation of the apparatus. In the event that the algorithm detects that there is a problem with the user interface and/or apparatus hardware a “failed self-test” alarm condition will signalled and the algorithm will hold this alarm until the device is reset.

If no problems during self-test routine 80 are detected, the algorithm will proceed to routine 81 in which the algorithm will pause for a random period prior to proceeding to “desynchronise” the device from other simultaneously started devices. Voltage and current measurements may be used to determine 5-second average values of V_{A5}, I_{A5} and I_{NS} using a ¼ filter. 5-minute average values of V_{A300}, I_{A300} and I_{N300} may be determined using a filter for a 300-second time constant. The device will measure current in the active phase conductor I_{A}, current in the neutral conductor I_{N}, and active-neutral voltage V_{A}. Values may then be calculated for V_{A5}, I_{A5}, and I_{NS} and V_{A300}, I_{A300} and I_{N300}, and for I_{N}/I_{A} and I_{NS}/I_{A5}.

Following initial measurement of voltage, active and neutral line currents the algorithm will proceed to routine 82 and the following initial conditions will be tested. If I_{N}/I_{A}<5% then signal “broken neutral” alarm. If I_{N}/I_{A}<30% then signal “impaired neutral” alarm.

The algorithm will next enter a primary operational routine loop. The first subroutine 83 will initiate a program hold for a random period prior to proceeding in order to “desynchronise” the device from other simultaneously started devices.

The algorithm will next move to subroutine 84 which will perform a series of active impedance tests involving switching of a know impedance in and out of the network circuit so as to minimise impact on measurement of V, I_{A} and I_{N}, of changes in current flows and voltages that may result from naturally occurring random switching of impedances within an electrical network, or that may result from deliberate or planned switching of impedance in an electrical network.

With the impedance switched out and then switched in, measurements of the line voltage, active and neutral line currents are performed under each condition with each measurement averaged over a defined interval.

This series of measurements may be repeated to determine a reliable average value over a short time period and the resulting averages logged to memory.

Calculate active-return path loop impedance Z_{ANE} using measured voltage and currents.

Z_{ANE}=(V₁−V₂)/(I_{A2}−I_{A1})

confirm

Z_{ANE}=(V₂−V₁)*(230/V₁)

Calculate active-neutral path loop impedance Z_{AN} and active-earth return path loop impedance Z_{AE} when impedance switched in.

Z_{AN}=Z_{ANE}*I_{A2}/I_{N2}

Z_{AE}=Z_{ANE}*I_{A2}/(I_{A2}−I_{N2})

Calculate covariance of loop impedances vs active currents.

Covariance C_{AN} of Z_{AN} vs I_{A},

Covariance C_{AE} of Z_{AE} vs I_{A},

Covariance C_{ANE} of Z_{ANE} vs I_{A}

The measured and calculated values may be compared with previously logged values and programmed limits subroutine 85, as follows and actions taken as required.

If Z_{AN}>1.0 Ohm then signal “broken neutral” alarm.

Z_{AE}>10 Ohm then signal “impaired earth” alarm.

Z_{ANE}>1.0 Ohm then signal “impaired active” alarm.

C_{AN}>2.0 then add 1 to counter CO_{A}

C_{AE}>5.0 then add 2to counter CO_{A}

C_{ANE}>2.0 then add 3 to counter CO_{A}

CO_{A}=5 then signal possible hot joint on active

CO_{A}=1 or 4 then signal possible hot joint on neutral

CO_{A}=2 or 5 then signal possible hot joint on earth

The algorithm will now enter a passive monitoring loop subroutine 86 and will perform measurements of line voltage, active and neutral currents with each measurement averaged over a defined interval. These values will be used in the calculation of the running averages, V₀₅, I_{A05}, I_{N05} and V₀₃₀₀, I_{A0300}, I_{N0300}.

Following these measurements of voltage, active and neutral line currents subroutine 87 will make the following calculations, log the specified values to memory and take any required actions.

Calculate the value for I_{N}/I_{A} and I_{N5}/I_{A5}

If I_{N}/I_{A}<5% then log “broken neutral” alarm

If I_{N}/I_{A}<30% then log “impaired neutral” alarm

If I_{N}/I_{A}>105% then log “reverse current flow” alarm

If 1−{(I_{N}/I_{A})/(I_{N5}/I_{A5})}>25% or <−25% then run Active Test

Subroutine 88 will make the following calculations, and take any required actions.

If V_{A300}>270 V then signal “voltage higher than regulatory maximum” and proceed.

If V_{A300}<200 then signal “voltage lower than regulatory minimum” and proceed.

Subroutine 89 will determine if a scheduled self test is required.

Subroutine 91 will determine if a scheduled active test is required.

Return to start of passive monitoring loop, subroutine 86.

Finally, it is to be understood that various alterations, modifications and/or additions may be introduced into the constructions and arrangements of parts values and/or parameters previously described without departing from the spirit or ambit of the following claims.

What is claimed is:

1. An apparatus for detecting a discontinuity or impedance irregularity in an active line, a neutral return line and/or an earth return path of an electrical power distribution network including the active line, neutral return line and earth return path, the apparatus comprising:
means for measuring a change in voltage and/or current flow associated with a deliberate switching of a known impedance and/or a naturally occurring random switching of an impedance in the electrical network, wherein the change in voltage and/or current flow is due to a discontinuity or impedance irregularity in the active line, neutral line and/or earth return path;
means for implementing a first algorithm for identifying the discontinuity or impedance irregularity in presence of allowable variation in voltage and/or current flow that may mimic or hide a discontinuity or impedance irregularity in the active line, neutral return line and/or earth return path including a reverse current flow through the earth return path; and
means for comparing a result of the measuring with a reference to provide an indication of the discontinuity or impedance irregularity.

2. The apparatus of claim 1, wherein the first algorithm is configured to identify the discontinuity or impedance irregularity in presence of allowable variation in nominal supply voltage to the electrical network including a voltage change resulting from network operations that mimic or hide a discontinuity or impedance irregularity in the active line, neutral return line and or earth return path.

3. The apparatus of claim 1, further comprising means for implementing a second algorithm that includes an estimation of magnitude and condition of serial and parallel impedances of the active and neutral lines and the earth return path in presence of allowable variation in nominal supply voltage to the electrical network including a voltage change resulting from network operations that mimic or hide a discontinuity or impedance irregularity in the active line, neutral return line and/or earth return path.

4. The apparatus of claim 3, wherein the second algorithm includes an estimation of variation in current flow that may mimic or hide a discontinuity or impedance irregularity in the active line, a neutral supply line and/or earth return path including a reverse current flow through the earth return path that may alter current flow between the active and neutral lines and the earth return path.

5. The apparatus of claim 1, wherein the algorithm is configured to discriminate a network that includes a discontinuity or impedance irregularity in the active line, neutral return line and/or earth return path from a network that does not include a discontinuity or impedance irregularity in the active line, neutral return line and/or earth return path in presence of anomalies in the supply voltage and current flow.

6. The apparatus of claim 1, wherein the reference is configured to discriminate a network that includes a discontinuity or impedance irregularity in the active line, neutral return line and/or earth return path from a network that does not include a discontinuity or impedance irregularity in the active line, neutral return line and/or earth return path.

7. The apparatus of claim 1, wherein the reference includes data samples obtained from a plurality of sites when the network does not include a discontinuity or impedance irregularity in the active line, neutral return line and/or earth return path.

8. The apparatus of claim 1, wherein the reference includes data samples obtained from a plurality of sites when the network does include a discontinuity or impedance irregularity in the active line, neutral return line and/or earth return path.

9. The apparatus of claim 2, further comprising means for measuring changes in voltage and/or current flow in the network that result from random or natural switching of impedances in the network.

10. The apparatus of claim 2, further comprising means for measuring changes in voltage and/or current flow in the network that result from the deliberate switching of a known impedance or the naturally occurring random switching of an impedance in the network.

11. The apparatus of claim 1, wherein the means for measuring includes an analog to digital converter.

12. The apparatus of claim 1, wherein the means for comparing includes a microprocessor and a memory for storing data associated with the reference.

13. The apparatus of claim 1, wherein the indication includes an audible and/or visual alarm and/or an electrical signal.

14. A method of detecting a discontinuity or impedance irregularity in an active line, a neutral return line and/or an earth return path of an electrical power distribution network including the active line, neutral return line and earth return path, the method comprising:
measuring a change in voltage and/or current flow associated with a deliberate switching of a known impedance and/or a naturally occurring random switching of an impedance in the electrical network wherein the change in voltage and/or current flow is due to a discontinuity or impedance irregularity in the active line, neutral line and/or earth return path;
implementing a first algorithm configured to identify the discontinuity or impedance irregularity in presence of allowable variation in voltage and/or current flow that may mimic or hide a discontinuity or impedance irregularity in the active line, neutral return line and/or earth return path including a reverse current flow through the earth return path; and
comparing a result of the measuring with a reference to provide an indication of the discontinuity or impedance irregularity.

15. The method of claim 14, wherein the first algorithm is configured to identify the discontinuity or impedance irregularity in presence of allowable variation in nominal supply voltage to the electrical network including a voltage change resulting from network operations that mimic or hide a discontinuity or impedance irregularity in the active line, neutral return line and/or earth return path.

16. The method of claim 14, further comprising implementing a second algorithm that includes an estimation of magnitude and condition of serial and parallel impedances of the active and neutral lines and the earth return path in presence of allowable variation in nominal supply voltage to the electrical network including a voltage change resulting from network operations that mimic or hide a discontinuity or impedance irregularity in the active line, neutral return line and/or earth return path.

17. The method of claim 16, wherein the second algorithm includes an estimation of variation in current flow that may mimic or hide a discontinuity or impedance irregularity in the active line, a neutral supply line and/or earth return path including a reverse current flow through the earth return path that may alter current flow between the active and neutral lines and the earth return path.

18. The method of claim 14, wherein the algorithm is configured to discriminate a network that includes a discontinuity or impedance irregularity in the active line, neutral return line and/or earth return path from a network that does not include a discontinuity or impedance irregularity in the active line, neutral return line and/or earth return path in presence of anomalies in the supply voltage and current flow.

19. The method of claim 14, wherein the reference is configured to discriminate a network that includes a discontinuity or impedance irregularity in the active line, neutral return line and/or earth return path from a network that does not include a discontinuity or impedance irregularity in the active line, neutral return line and/or earth return path.

20. The method of claim 14, wherein the reference includes data samples obtained from a plurality of sites when the network does not include a discontinuity or impedance irregularity in the active line, neutral return line and/or earth return path.

21. The method of claim 14, wherein the reference includes data samples obtained from a plurality of sites when the network does include a discontinuity or impedance irregularity in the active line, neutral return line and/or earth return path.

22. The method of claim 14, further comprising measuring changes in voltage and/or current flow in the network that result from random or natural switching of impedances in the network.

23. The method of claim 14, further comprising measuring changes in voltage and/or current flow in the network that result from the deliberate switching of a known impedance or the naturally occurring random switching of an impedance in the network.

24. The method of claim 14, wherein the measuring is performed by means including an analog to digital converter.

25. The method of claim 14, wherein the comparing is performed by means including a microprocessor and a memory for storing data associated with the reference.

26. The method of claim 14, wherein the indication includes an audible and/or visual alarm and/or an electrical signal.

27. An apparatus for detecting a discontinuity or impedance irregularity in an active line, a neutral return line and/or an earth return path of an electrical power distribution network including the active line, neutral return line and earth return path, the apparatus including:
a measuring unit configured to measure a change in voltage and/or current flow associated with a deliberate switching of a known impedance and/or a naturally occurring random switching of an impedance in the electrical network, wherein the change in voltage and/or current flow is due to a discontinuity or impedance irregularity in the active line, neutral line and/or earth return path;
an implementing unit configured to implement a first algorithm for identifying the discontinuity or impedance irregularity in presence of allowable variation in voltage and/or current flow that may mimic or hide a discontinuity or impedance irregularity in the active line, neutral return line and/or earth return path including a reverse current flow through the earth return path; and
a comparing unit configured to compare a result of the measuring with a reference to provide an indication of the discontinuity or impedance irregularity.
